(19) United States
(12) Patent Application Publication
(10) Pub. No.: US 2025/0185312 A1
(43) Pub. Date: Jun. 5, 2025

(54) METHOD FOR PRODUCING A SEMICONDUCTOR COMPONENT, AND SEMICONDUCTOR COMPONENT

(71) Applicants: Alberto Martinez-Limia, Pliezhausen (DE); Daniel Krebs, Aufhausen (DE); Dragos Costachescu, Reutlingen (DE); Holger Bartolf, Ofterdingen (DE); Jan-Hendrik Alsmeier, Pfullingen (DE); Klaus Heyers, Reutlingen (DE); Stephan Schwaiger, Bodelshausen (DE); Wolfgang Feiler, Reutlingen (DE)

(72) Inventors: Alberto Martinez-Limia, Pliezhausen (DE); Daniel Krebs, Aufhausen (DE); Dragos Costachescu, Reutlingen (DE); Holger Bartolf, Ofterdingen (DE); Jan-Hendrik Alsmeier, Pfullingen (DE); Klaus Heyers, Reutlingen (DE); Stephan Schwaiger, Bodelshausen (DE); Wolfgang Feiler, Reutlingen (DE)

(21) Appl. No.: 18/956,851

(22) Filed: Nov. 22, 2024

(30) Foreign Application Priority Data
Dec. 1, 2023 (DE) 10 2023 212 057.7

(51) Int. Cl. H10D 62/10; H10D 30/01; H10D 30/66

(52) U.S. Cl. CPC H10D 62/102; H10D 30/0297; H10D 30/668

(57) ABSTRACT

A method for producing a semiconductor component. The method includes: providing a substrate and/or drain layer, a first-type doped drift and/or spread layer applied to the substrate and/or drain layer, a channel layer applied to the drift and/or spread layer, and a first-type doped source layer inserted into the channel layer and/or applied to the channel layer; forming a gate trench, which extends in the vertical direction from the source layer into the drift and/or spread layer; and forming a second-type doped shielding region, which extends in the vertical direction into the drift and/or spread layer. The shielding region has a lateral distance from the gate trench, so that a channel region corresponding to the lateral distance remains in the channel layer, and at least part of the shielding region extends in the vertical direction to below the gate trench.

### FIELD

The present invention relates to a method for producing a semiconductor component and to such a semiconductor component, in particular a transistor, in particular a so-called trench MOSFET.

### BACKGROUND INFORMATION

Field-effect transistors, in particular so-called MOSFETs or MISFETs, are used in various fields. A variant thereof are so-called trench MOSFETs or T-MOSFETs, in which one channel is vertical. Here, for example, an n-doped source layer and a channel layer located between this source layer and one of the n-doped drift layer are interrupted by trenches; gates are then arranged in such trenches.

### SUMMARY

According to the present invention, a method for producing a semiconductor component and a semiconductor component are provided. Advantageous example embodiments of the present invention are disclosed herein.

The present invention relates to semiconductor components, in particular field-effect transistors, and in particular to trenches, and the production thereof. Different types of doping, specifically n-doping and p-doping, are used with semiconductor materials, wherein different components can be doped differently. For the sake of clarity, field-effect transistors are to be described below with a specific type of doping; n-doping is intended to be a doping of a first type, p-doping is intended to be a doping of a second type. However, it is understood that n-doping and p-doping can also be interchanged; i.e., the n-doping could be the second type of doping and the p-doping could be the first type of doping.

Such a field-effect transistor typically has a substrate and/or drain layer, an n-doped drift and/or spread layer (but also possibly, for example, just a drift layer) applied to the substrate and/or drain layer, a channel layer (usually p-doped) applied to the drift and/or spread layer and an n-doped source layer inserted into the channel layer and/or applied to the channel layer. The substrate and/or drain layer can also have a so-called buffer layer between the substrate and drain layers. In addition, a gate trench, a so-called trench, is provided, which extends in the vertical direction from the source layer into the drift and/or spread layer. A gate with a gate electrode is then inserted into it, wherein the gate electrode is usually surrounded by a gate dielectric or gate oxide.

Furthermore, such a field-effect transistor usually has a source contact material layer that borders on the source layer. The gate or gate electrode, on the other hand, is insulated from the source contact material layer. Likewise, such a field-effect transistor has a drain contact material layer that borders on the substrate and/or drain layer. The source contact material layer serves as the source electrode or connection, while the drain contact material layer serves as the drain electrode or connection.

It should be mentioned that this type of field-effect transistor can have a plurality of such gate regions or gate trenches and gate electrodes. So-called fins or mesas, in which the aforementioned layers are formed, are then formed between the gate regions. This is a particular advantage of a trench MOSFET, since the vertical arrangement means that many gate electrodes can be arranged next to one another.

Such a field-effect transistor can be used alone or together with others, e.g. as a power switch. Preferred fields of application are, for example, in an electric drive train of a vehicle, e.g. in a current transformer (DC/DC converter, inverter), in charging devices for electrically powered vehicles or in solar inverters.

A particular advantage of a trench MOSFET is, for example, that the vertical arrangement makes it possible to arrange many gate electrodes next to one another per unit area. The field-effect transistor can in particular be formed as a SiC or GaN field-effect transistor, i.e., a substrate and/or commonly used semiconductor material can be silicon carbide (SiC) or gallium nitride (GaN), since these semiconductor materials have a wide band gap. However, semiconductor materials having an ultra-wide band gap, e.g. gallium oxide, can also be considered. However, the present invention can in general also be used with other semiconductor materials, such as gallium nitride (GaN), silicon (Si) or germanium (Ge).

A challenge with such field-effect transistors, e.g., silicon carbide (SiC) trench-gate-power MISFETs, is to achieve good forward properties (i.e., a low area-specific resistance) with good resistance to short-circuiting and to also limit the maximum field strength in the insulator of the trench to acceptable values, e.g., in the order of magnitude of 3 MV/cm, at a high blocking voltage for reasons of reliability.

One possibility for achieving a good resistance to short-circuiting is to limit the current density in the event of a short circuit to the smallest possible values since the power loss density and the heating rate of the field-effect transistor or of a component in which the field-effect transistor is contained is thus limited and timely switching-off of the component before it is damaged or destroyed can be made possible. Ideally, this is achieved while maintaining a low area-specific resistance in the forward bias case.

An important measure for increasing the short-circuit strength can be the reduction of the currents flowing in the short circuit by reducing the channel length modulation. For this purpose, the pn transition between the body zone (channel layer) and the drift and/or spread layer must be shielded from high electric fields. In SiC trench MISFETs, this can be, for example, a vertically deep p− or p+-doped shielding zone that extends in the vertical direction into the drift and/or spread layer, is laterally spaced from the gate trench, and extends in the vertical direction to below the gate trench.

However, certain problems have arisen here. For achieving a large vertical depth of the shielding region, so-called high-energy implants in the MeV range are usually necessary, which result in the p− or p+ profile (i.e., the profile of the shielding region) not being very abrupt laterally and vertically, but rather its doping concentration decaying with a moderate steepness as a result of tails and lateral under-scattering under the mask required for its patterning; furthermore, these MeV processes are cost-intensive and damage the crystal, e.g. a 4H—SiC crystal.

A nominal distance of the shielding zone to the gate trench or trench in the lateral direction must not be less than a certain minimum distance due to alignment tolerances, since in the case of imperfect alignment, the threshold voltage increases in the forward bias case and the specific on-resistance increases.

Such alignment tolerances lead to the current being distributed asymmetrically in the event of a short circuit, because the JFET resistors between the shielding regions and the zones to the left and right of the gate trench are of different sizes or widths. As a result, the current always flows through the JFET region (channel layer) with the lower electrical resistance.

It is provided according to the present invention that the p− doped shielding region is formed using self-alignment, in particular by means of implantation. Due to the self-alignment, a predefined lateral distance of the shielding region to the gate trench is achieved, so that a channel region corresponding to the predefined lateral distance remains in the channel layer. A part of the channel layer thus becomes the shielding region. The shielding region is formed in such a way that at least a part of the shielding region extends in the vertical direction to below the gate trench.

The use of masks and/or filling material, by means of which masks are also formed, can be provided. This will be discussed in more detail below and within the context of the description of the figures.

This self-alignment allows the lateral distance of the shielding zone from the gate trench to be formed as precisely as desired.

In one example embodiment of the present invention, forming the shielding region includes forming, in particular by means of implantation and using a first mask for self-alignment, a first partial shielding region of the shielding region, and forming, in particular by means of implantation and using a second mask for self-alignment, a second partial shielding region of the shielding region. A lateral width of the first mask is selected according to the predefined lateral distance of the shielding region to the gate trench. The second partial shielding region extends in the vertical direction to below the gate trench and deeper than the first partial shielding region, and the second partial shielding region is arranged in the lateral direction at most as close to the gate trench as the first partial shielding region.

The second partial shielding region can in particular correspond to the shielding region mentioned at the beginning. In this case, an additional shielding region (here, the first) is provided, which does not extend as deep vertically, but allows more precise adjustment of the lateral distance from the gate trench. Likewise, the first partial shielding region can be inserted with lower implant energy than the second partial shielding region, making it more abrupt and thus causing less channel length modulation. The implantation profile can be retrograde.

Due to the self-aligned formation of the shielding region to the gate trench, it can be arranged particularly close to the gate trench-side surface of the channel layer, which further reduces the channel length modulation.

In one example embodiment of the present invention, the second partial shielding region can also be designed deeper, so that the electric field strength at the curvature of the gate trench is reduced, which is advantageous in terms of reliability.

In one example embodiment of the present invention, prior to the formation of the shielding region, a first shielding trench is formed, which extends in the vertical direction into the channel layer and is spaced further from the gate trench in the lateral direction than the shielding region (still to be formed). The first shielding trench can preferably be generated in a manner self-aligned to the gate trench. As a result, the first partial shielding region is also self-aligned to the gate trench and can be designed particularly abruptly using even reduced implantation energy.

In one example embodiment of the present invention, after the formation of the first partial shielding region and prior to the formation of the second partial shielding region, a second shielding trench is formed, which extends in the vertical direction into the channel layer and is spaced further from the gate trench in the lateral direction than the first shielding trench.

The second shielding trench is preferably designed to be self-aligned to the gate trench. As a result, the second partial shielding region is also self-aligned to the gate trench and can be produced more abruptly and with less effort with reduced implantation energy, since the required implantation energies can be reduced.

As mentioned, the second partial shielding region—or the shielding region in general—can be designed to be self-aligned to the gate trench. As a result, its nominal distance to the gate trench can be reduced compared with the case without self-alignment. This leads to an improved shielding effect both in terms of the field penetration to the channel layer and the gate trench with its corners/curvatures. Furthermore, the current distribution is homogenized in the event of a short circuit.

In one example embodiment of the present invention, forming the shielding region comprises forming, in particular by means of implantation, a first partial shielding region of the shielding region and the channel region, and forming, in particular by means of implantation and using a (second) mask for self-alignment, a second partial shielding region of the shielding region.

The first partial shielding region and the channel region are formed in such a way that the channel layer is doped in accordance with the first partial shielding region and that the channel region is formed by means of counter-doping. The second partial shielding region extends in the vertical direction to below the gate trench and deeper than the first partial shielding region, and the second partial shielding region is arranged in the lateral direction at most as close to the gate trench as the first partial shielding region. The formation of the second partial shielding region can thus be carried out in particular as already mentioned above.

In one example embodiment of the present invention, the formation of the first partial shielding region and the channel region is carried out prior to the formation of the gate trench, wherein forming the gate trench comprises removing a part of the channel layer, in such a way that the channel region remains.

In one example embodiment of the present invention, the formation of the first partial shielding region is carried out prior to the formation of the gate trench, whereas the formation of the channel region is carried out after the formation of the gate trench, in particular by means of oblique implantation, over the gate trench.

It is understood that further steps may be necessary for the final field-effect transistor, e.g., the insertion of the gate, the formation of the contact material layers, an edge termination along with contact path extensions and the like; here, conventional methods can be used, e.g., according to the related art in micro- and nanotechnology.

Specific variants of the various example embodiments and combinations thereof, along with their various advantages, will be explained in more detail below with reference to the figures.

Further advantages and example embodiments of the present invention can be found in the description and the figures.

The present invention is shown schematically in the figures on the basis of exemplary embodiments and is described below with reference to the figures.

### BRIEF DESCRIPTION OF THE DRAWINGS

FIG. 1 schematically shows a field-effect transistor for explaining the background of the present invention.

FIGS. 2A, 2B, 3, and 4 show field-effect transistors in different example embodiments of the present invention.

FIG. 5 to 9 show schematic sequences of methods for producing a field-effect transistor in various embodiments of the present invention.

### DETAILED DESCRIPTION OF EXAMPLE EMBODIMENTS

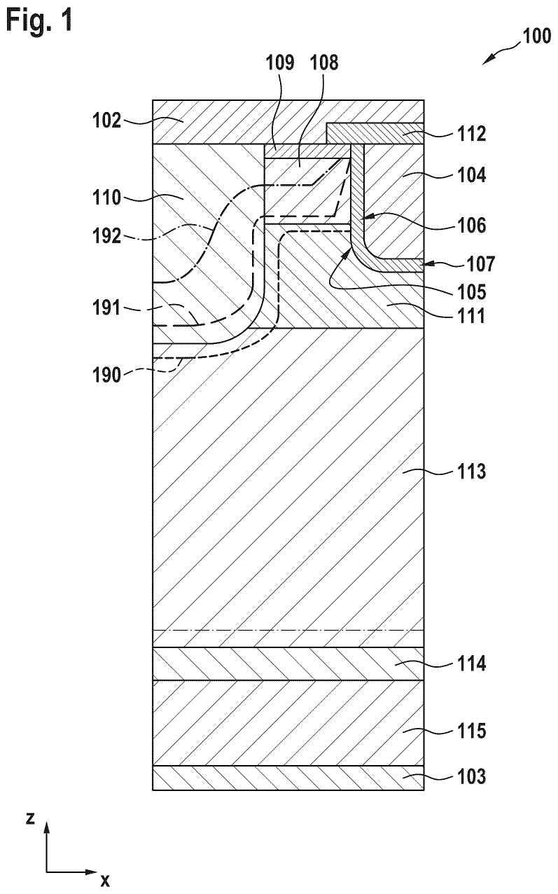

FIG. 1 schematically shows a field-effect transistor 100, or generally a semiconductor element, for explaining the present invention, in particular an active cell of an otherwise larger field-effect transistor. The field-effect transistor is formed as a so-called trench MISFET. A sectional view of the field-effect transistor is shown, where the z-direction is the vertical direction; the field-effect transistor has a larger extension in each case in the xy-plane (the y-direction here is into the plane of the drawing).

In the following, the field-effect transistor with an n-doping as doping of the first type and a p-doping as doping of the second type will be described. As already mentioned, the types of doping can also be reversed.

The field-effect transistor 100 according to FIG. 1 has a substrate and/or drain layer, here in particular a substrate layer 115 with an optional buffer layer 114 applied thereon (e.g., n+-doped). In addition, the field-effect transistor 100 has an n-doped drift and/or spread layer applied thereto, here in particular an n-doped drift layer 113 (e.g., as an epi layer) and an optional spread layer 111. If the spread layer 111 is not provided, the drift layer 113 extends further upward instead of the spread layer 111.

In addition, the field-effect transistor 100 has a channel layer 108 (also referred to as body zone, usually p-doped) applied to the drift and/or spread layer, along with an n-doped source layer 109 (e.g., also n+-doped). The source layer 109 is inserted into the channel layer and/or applied to the channel layer.

Furthermore, the field-effect transistor 100 has a gate trench 105, which extends in the vertical direction from the source layer 109 into the drift and/or spread layer 113, 111. The gate trench 105 is typically formed with curvatures on the corners, as shown here.

In addition, the field-effect transistor 100 has a p-doped shielding region 110, which extends in the vertical direction into the drift and/or spread layer 113, 111, is laterally spaced from the gate trench 105, and extends in the vertical direction to below the gate trench 105.

The shielding region 110 can be formed in particular by means of implantation into the channel layer, so that the channel region 108 shown remains of the channel layer.

Furthermore, the field-effect transistor 100 has a gate with a gate electrode 104. The gate electrode 104 is surrounded by a gate dielectric 106 at the gate bottom and a gate dielectric 107 at the side (the thicknesses of 106 and 107 may differ). In addition, an intermediate dielectric 112 is provided.

The intermediate dielectric 112 consists, for example, of SiO2, but can also be another insulating dielectric. The gate dielectric 107 at the gate trench bottom consists, for example, of SiO2, but can also be another insulating dielectric. The gate dielectric 106 consists, for example, of SiO2, but can also be another insulating dielectric, e.g. a high-k dielectric, or consist of multilayer systems of these or alternative dielectrics, such as Si3N4, Al2O3, etc.

The field-effect transistor 100 also has a drain contact material layer 103, e.g. a drain electrode, which here borders on or is contacted with the substrate layer 115. The field-effect transistor 100 also has a source contact material layer 102, e.g. a source electrode, which borders on or is contacted with the source layer 109. However, due to the intermediate dielectric 112, the gate electrode 104 is separated from the source contact material layer 102.

The mode of operation of the field-effect transistor 100 will be explained below. Adjoining or even interpenetrating zones or layers of the same doping type (n or p) are conductively connected to one another. Likewise, the contacts between the metal and the semiconductor are to be understood as low-resistance ohmic contacts, such as between the source contact material layer 102 and the source zone 109 and the shielding zone 110 or the drain contact material layer 103, and the substrate layer 115.

Starting from doping concentrations with n, p without any additional symbols, n−, p− designate significantly lower and n+, p+ significantly higher doping concentrations of at least a factor of 10 compared with the concentrations without any additional symbols. The source potential is intended to serve as a reference potential in the following explanation of the mode of operation.

In the forward bias case, the source contact material layer 102 is at the source potential, the gate or gate electrode 104 is at a positive gate potential and the drain contact material layer 103 is at a small positive drain potential of a few volts. If the gate potential is below the so-called threshold voltage, Vth, only a small reverse current flows from drain to source, i.e. from the drain contact material layer 103 to the source contact material layer 102. If the gate voltage of the gate is increased above Vth, so many electrons are attracted to the gate insulator-side surface of the body zone 108 (channel region) laterally adjacent to the gate trench 105 by the influence effect that a conductive inversion channel is formed there (here, the charge polarity is inverted compared with the body zone 108).

This opens a low-resistance current path from the drain contact material layer 103, through the substrate layer 115, the optional buffer layer 114, the drift and/or spread layer 111, 113, the channel formed on the gate insulator-side surface of the body zone 108 and the source layer 109 to the source contact material layer 102, and the component is able to carry a high current density and has a small specific on-resistance Ron*A (where A is the active area of the MISFET). The boundary of the space charge zone is outlined for this operating case in FIG. 1 by the dashed line 190, 191. The optional spread layer 111 increases conductivity and thus contributes to the low on-resistance.

In the blocking case, the gate voltage is below Vth and the drain voltage is a positive voltage. With increasing drain voltage, the space charge zones of the pn transitions between the p− or p+-doped zones (shielding region 110, channel region 108) and the adjacent, in each case lower n-doped zones (drift and/or spread layer 111, 113) into the low n-doped zones; with increasing blocking voltage also further into the drift layer 113, while the p-doped zones (shielding region 110, channel layer 108) are not completely depleted. The shielding zone 110 serves to limit the electric field strength, in particular at the corners/curvatures of the gate trench 105 and also at its bottom, wherein the curvatures are preferably formed such that the peaks of the electric field forming there make possible a defined reliability of the component. Furthermore, it limits the electric field at the pn transition between the body zone or channel layer 108 and the drift zone (drift and/or spread layer 111, 113).

The effect in relation to limiting the electric field strength is stronger the deeper the shielding region 110 extends in the vertical direction into the drift zone (drift and/or spread layer 111, 113), the more highly and abruptly it is doped and the smaller its lateral distance from the gate trench 105. However, due to alignment tolerances between shielding region 110 and gate trench 105, the nominal distance of the shielding region 110 without tolerances must not be less than a certain minimum distance to gate trench 105, since in the event of imperfect alignment, the threshold voltage will otherwise rise in the forward bias case and the specific on-resistance Ron*A will increase.

In the short circuit case, if a high voltage is applied to the drain contact material layer 103 and a voltage above the threshold voltage Vth is applied to the gate, a high current flows through the component. The boundary of the space charge zone (SPZ) for this operating case is outlined in FIG. 1 by the dash-dot line 192. It can be seen that the space charge zone extends significantly further into the body zone 108 due to the high voltage than in the forward bias case. As a result, the effective channel length is shortened, which is an additional cause of high currents in this operating case in addition to the usual current increase according to the MISFET characteristic. Furthermore, the component becomes susceptible to short-channel effects such as DIBL and premature breakdown (punch) in the short circuit case.

The shielding region 110 serves to limit the electric field strength, in particular at the corners/curvatures of the gate trench 105 and also at its bottom. Furthermore, it limits the electric field at the pn transition between the body zone or channel region 108 and the drift zone (drift and/or spread layer 111, 113) and thus helps to counteract the shortening of the effective channel length. The effect in relation to limiting the electric field strength is stronger the deeper the shielding region 110 extends in the vertical direction into the drift zone, the more highly and more abruptly it is doped and the smaller its lateral distance from the gate trench 105. However, due to alignment tolerances between the shielding region 110 and the gate trench 105, the nominal distance of the shielding region 110 without tolerances must not be less than a certain minimum distance to the gate trench 105, since in the event of imperfect alignment, the threshold voltage will otherwise rise in the forward bias case and the specific on-resistance will increase.

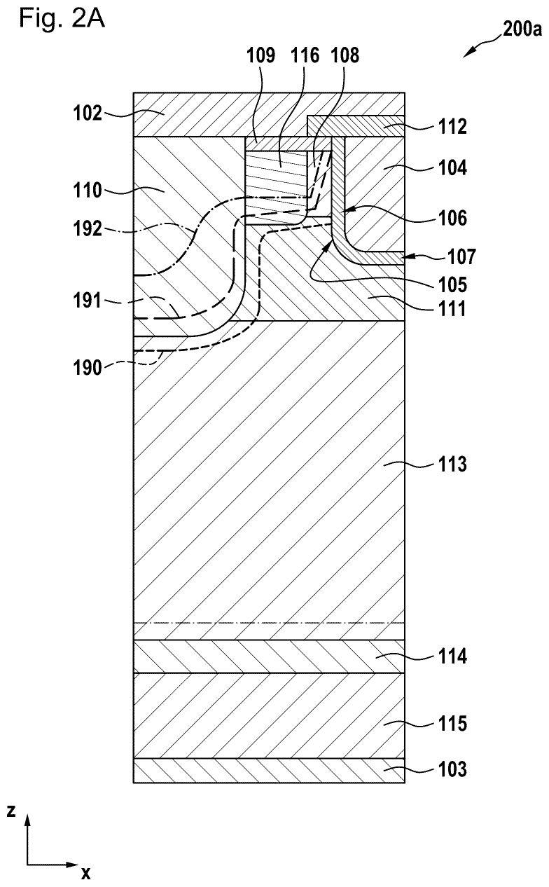

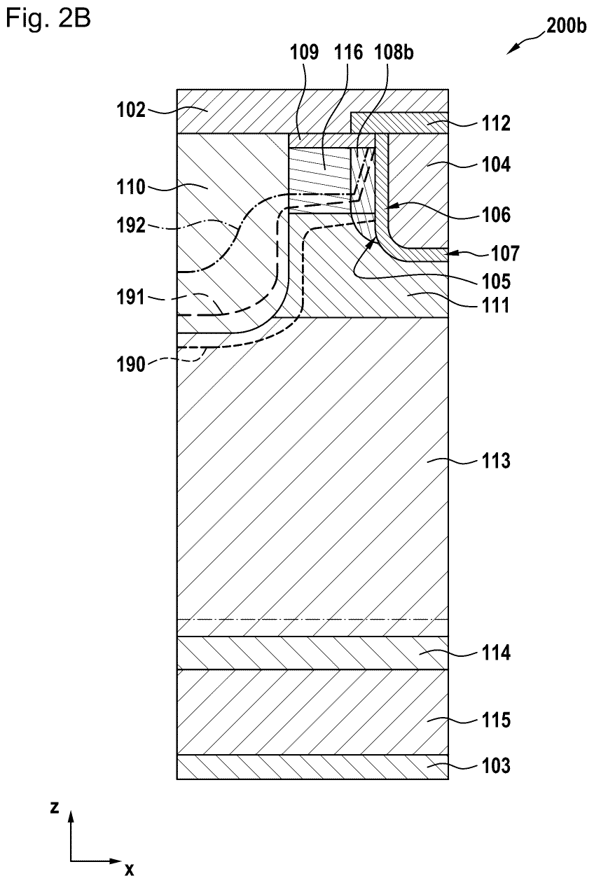

FIGS. 2a, 2b, 3 and 4 now schematically show field-effect transistors in various embodiments. The same reference signs should be used for identical or functionally equivalent elements and components as in FIG. 1. However, differences should be addressed explicitly.

The field-effect transistor 200a according to FIG. 2a has a p− doped shielding region, which comprises a first partial shielding region 116 and a second partial shielding region 110. The second partial shielding region 110 corresponds approximately to the shielding region of the field-effect transistor 100 according to FIG. 1, i.e. here the first partial shielding region 116, which is in particular p+-doped, is additionally present here.

The first partial shielding region 116 is vertically flatter than the second partial shielding region 110 and is arranged laterally (here, in the x-direction) at least as close to the gate trench 105 as the second partial shielding region 110, preferably even closer. As a result of the fact that the first partial shielding region 116 can be inserted with lower implantation energy than the second partial shielding region 110, it is more abrupt than the latter and thus causes a lower channel length modulation. The implantation profile of 116 may not be locally constant, e.g. retrograde; the implantation profile of 110 may not be locally constant, e.g. retrograde.

Due to the first partial shielding region 116, the channel region 108 is narrower in the lateral direction than in the field-effect transistor 100 according to FIG. 1.

As mentioned, the first partial shielding region 116 can be designed to be self-aligned to the gate trench 105 and can thus be arranged particularly close to the channel that can be generated on the trench-side surface of the channel layer or the channel region 108, which further reduces the channel length modulation.

The field-effect transistor 200b according to FIG. 2b has a p− or p+-implanted zone, which is compensated for in the net doping to a certain degree by means of a masked n-implantation (counter-doping or counter-implantation) in some zones. As a result, the pBody zone or the channel region, here designated by 108b, and the laterally adjacent first partial shielding region 116 are generated by a different process, but substantially with the same net doping and functionality as in the embodiment according to FIG. 2a.

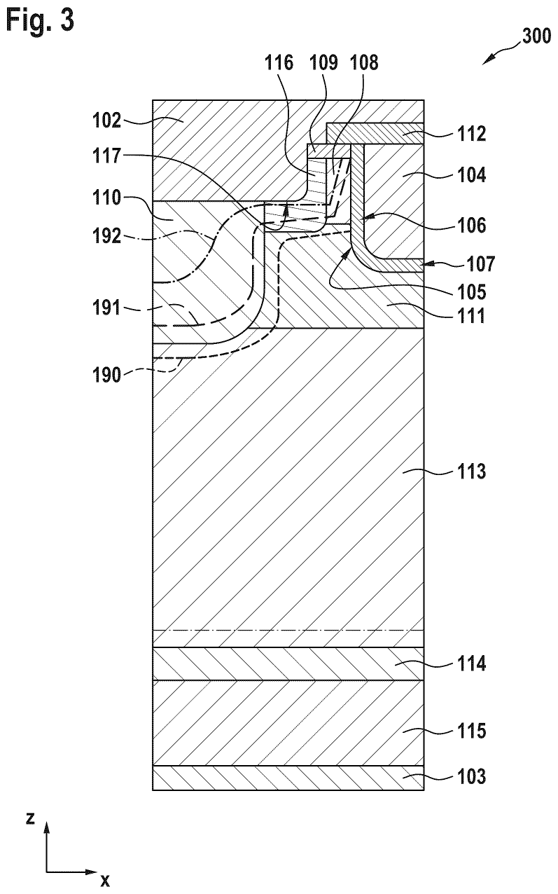

The field-effect transistor 300 according to FIG. 3 has, in addition to the field-effect transistor 200a according to FIG. 2a, a first shielding trench 117 that extends in the vertical direction into the channel layer and is spaced further from the gate 105 in the lateral direction than the shielding region. In this way, the second partial shielding region 110 can be designed deeper, thereby reducing the electric field strength at the curvature of the gate trench 105, which is advantageous in terms of reliability. In addition, the first partial shielding region 116 can be designed deeper with lower implant energy, as a result of which its doping profile is more abrupt and the shielding effect for the channel zone 108 is more effective.

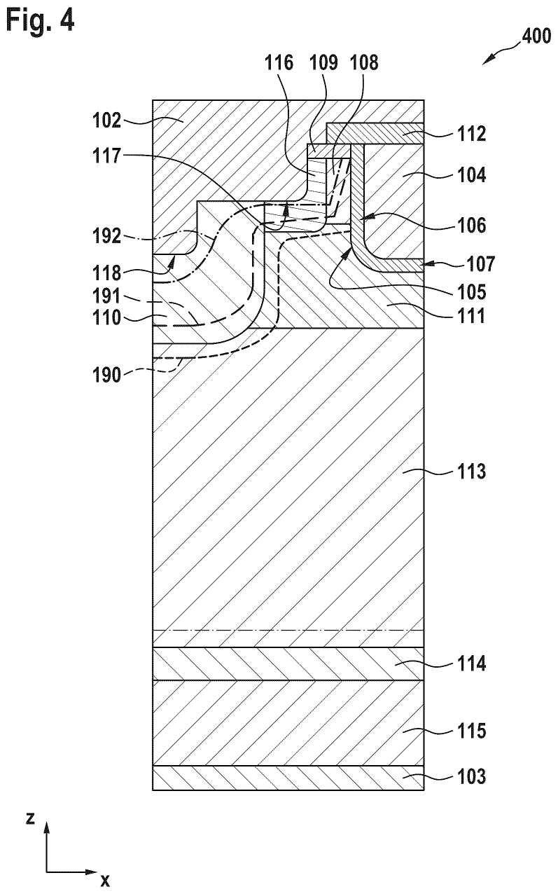

The field-effect transistor 400 according to FIG. 4 has, in addition to the field-effect transistor 300 according to FIG. 3, a second shielding trench 118 that extends in the vertical direction into the channel layer and is spaced further from the gate 105 in the lateral direction than the first shielding trench 117. In this way, the second partial shielding region 110 can be designed even deeper, thereby reducing the electric field strength at the curvature of the gate trench 105, which is advantageous in terms of reliability.

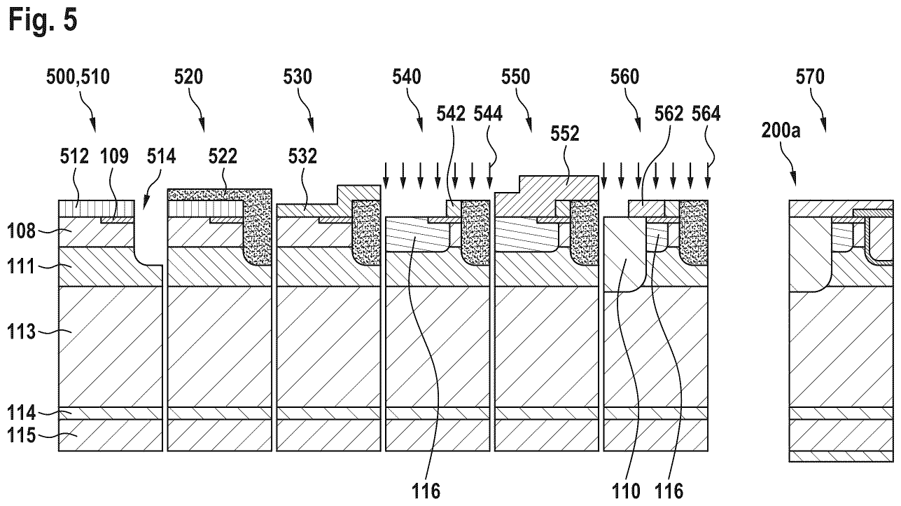

FIG. 5 to 9 now show schematic sequences of methods for producing a field-effect transistor in various embodiments. Identical elements, components or layers are designated by the same reference signs as in FIG. 1 to 4.

FIG. 5 shows an embodiment of a production method with which, for example, the field-effect transistor 200a according to FIG. 2a can be produced.

Initially, step 500, the substrate layer 115 with the optional buffer layer 114 applied thereon, the drift layer 113 applied thereon (e.g., as an epi layer), the optional spread layer 111, the channel layer applied thereon (here, 108 still designates the entire channel layer, later only a part of it remains as a channel region), and the source layer 109 are provided. Specifically, e.g., the buffer layer 114 and the drift zone (111, 113) can first be generated on the substrate layer 115 by means of epitaxy in a conventional manner. Subsequently, the spread layer 111 is doped, e.g. by means of implantation. Subsequently, the body zone or the channel layer 108 and the source layer 109 are implanted.

Furthermore, step 510, the gate trench 105 is formed, e.g. etched against a mask 512 (e.g., a hard mask, hereinafter also referred to as “zeroth patternable zone”), so that the pattern as shown for step 500 is created. Here, masks made of patternable material can be used for lateral patterning in a conventional manner.

In step 520, a first patternable material 522 is applied, wherein the gate trench 105 is thereby also filled.

In step 530, after etching back the first patternable material 522 (“recess etching”) and removing the residues of the zeroth patternable material or the mask 512, a second patternable material 532 is applied.

In step 540, after etching back the second patternable material 532 (recess etching), with the remainders of the first and second patternable material as a mask-referred to here as the first mask 542—the first partial shielding region 116 is formed in a manner self-aligned to the gate trench 105, in particular by means of implantation 544. At this point, it should be mentioned that the first partial shielding region 116 already has the desired lateral distance from the gate trench 105 along with the desired vertical depth, but also extends (further to the left of the gate trench) into a region in which the second partial shielding region will later be formed. Here, only the final channel region with the desired lateral width remains from the channel layer.

In step 550, a third patternable material 552 is applied.

In step 560, after etching back the third patternable material with the residues of the first, second and third patternable material as a mask-referred to here as the second mask 562—the second partial shielding region 110 is formed in a manner self-aligned to the gate trench 105, in particular by means of implantation 564. The second partial shielding region 110 extends in the vertical direction to below the gate trench 105 and deeper than the first partial shielding region 116.

Subsequently, step 570, the residues of the first, second and third patternable materials can be removed and the field-effect transistor can be completed in a conventional manner with further steps. These comprise, for example, a trench anneal, the thermal activation of the dopants, the application and patterning of the intermediate dielectric along with the source contact material layer and the passivation (not shown), grinding back the substrate layer 115 and applying the drain contact material layer.

The zeroth, first, second and third patternable materials comprise, for example, silicon dioxide, silicon nitride, polycrystalline silicon (doped or undoped) or photoresist or a combination of these materials. In particular, however, the zeroth differs in each case from the first, the first from the second and the second from the third material. The zeroth and the second, the zeroth and third along with the first and third can optionally be made of the same or a different material.

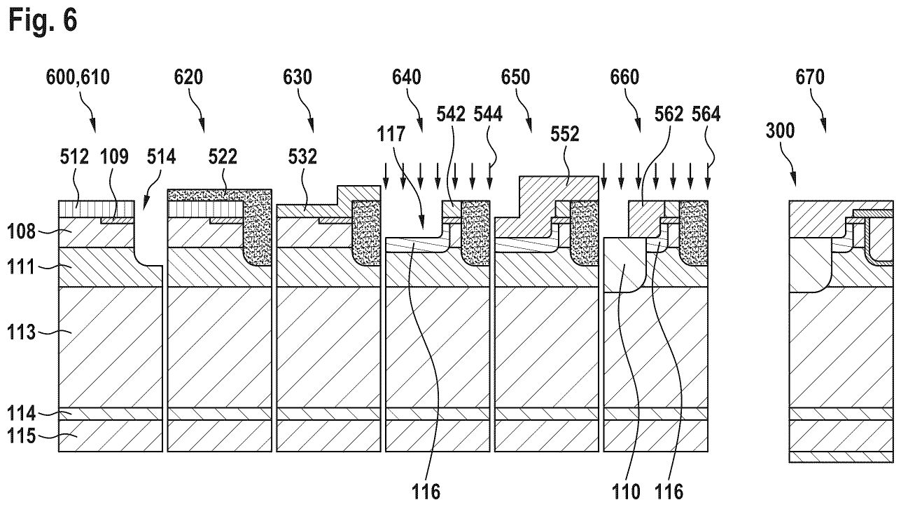

FIG. 6 shows an embodiment of a production method with which, for example, the field-effect transistor 300 according to FIG. 3 can be produced. Steps 600 to 670 correspond to steps 500 to 570 according to FIG. 5, but with the following differences. Therefore, the same elements or components as in FIG. 5 are designated by the same reference signs.

In step 640, in addition to step 540, the first shielding trench 117 is formed before the implantation 544 of the first partial shielding region 116 (this applies in particular per cell of the field-effect transistor). For this purpose, for example, the second patternable material is used as a mask (here, the mask 542), so that the first shielding trench 117 is self-aligned to the gate trench 105. The implantation of the first partial shielding region 116 is carried out in a self-aligned manner to the gate trench 105 with the second patternable material as a mask (here, the mask 542) into the first shielding trench 117.

In step 660, the formation or implantation 564 of the second partial shielding region 110 is carried out in a manner self-aligned to the gate trench 105 with the third patternable material as a mask into the first shielding trench 117.

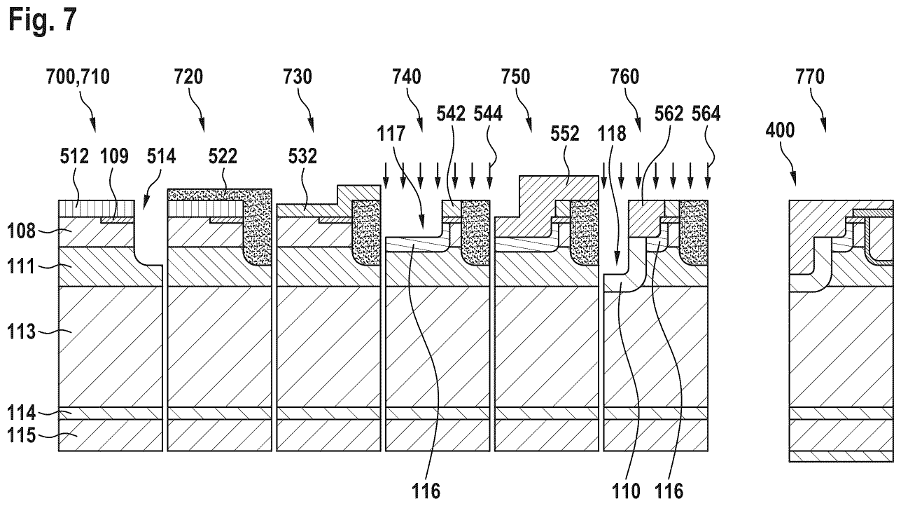

FIG. 7 shows an embodiment of a production method with which, for example, the field-effect transistor 400 according to FIG. 4 can be produced. Steps 700 to 770 correspond to steps 600 to 670 according to FIG. 6 (or these to a large extent to steps 500 to 570 according to FIG. 5), but with the following differences. Therefore, the same elements or components as in FIGS. 5 and 6 are designated by the same reference signs.

In step 760, in addition to step 660, the second shielding trench 118 is formed before the implantation of the second partial shielding region 110 (this applies in particular per cell of the field-effect transistor). For this purpose, the third patternable material is used as a mask (here, the mask 562), so that the second shielding trench 118 is self-aligned to the gate trench 105. The implantation of the second partial shielding region 110 is carried out in a manner self-aligned to the gate trench 105 with the third patternable material as a mask (here, the mask 562) into the second shielding trench 118.

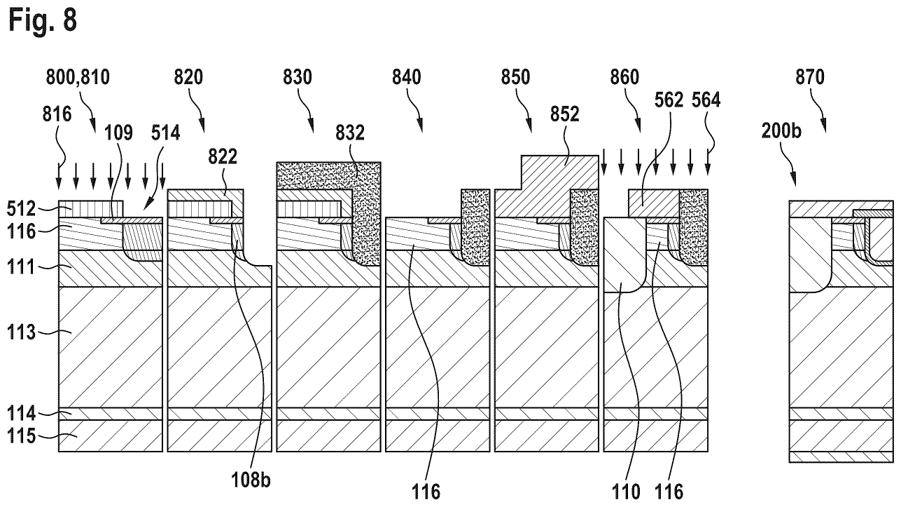

FIG. 8 shows an embodiment of a production method with which, for example, the field-effect transistor 200b according to FIG. 2b can be produced. Steps 800 to 870 correspond to steps 500 to 570 according to FIG. 5, but with the following differences. Therefore, the same elements or components as in FIG. 5 are designated by the same reference signs.

In step 800, a p− or p+ implantation 816 is additionally realized, specifically in the zone of the future channel region 108b and the first partial shielding region 116 (these two zones are not yet differentiated from one another at this point in time). The source layer 109 is implanted thereafter, for example.

In step 810, a masked (using the material 512 as a mask) n-implantation (for counter-doping) is thus realized, which partially compensates for p-doping already present in the channel layer or where the channel region 108b is to remain and reduces the net doping concentration. Thus, the channel region 108b and the laterally adjacent first partial shielding region 116 are generated. Here, the gate trench will be formed later.

In step 820, a patternable material 822 is applied, e.g. via an at least partially conformal deposition (“spacer concept”), the existing mask is widened and the gate trench 105 is formed or etched, so that the pattern as shown in step 820 is created. The channel region 108b hereby reaches its final lateral width.

In step 830, a new patternable material 832 is applied and the gate trench 105 is also filled with it. In step 840, after etching back the patternable materials, the filled gate trench 105 is exposed. In step 850, an additional patternable material 852 is applied. The material 832 can basically correspond to the material 522.

In step 840, unlike in step 540, no implantation is undertaken (this already took place in step 800); instead, material is removed.

In step 860, after etching back the additional patternable material, an unmasked region is exposed and there the second partial shielding region 110 is formed in a manner self-aligned to the gate trench 105, specifically by means of implantation 564 (as in step 560). However, the remaining material is used as the mask 562 here.

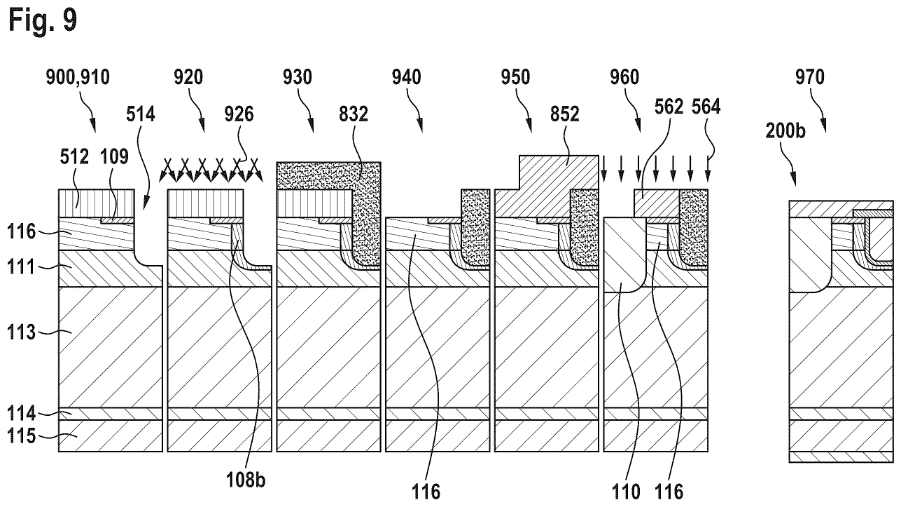

FIG. 9 shows an embodiment of a production method with which, for example, the field-effect transistor 200b according to FIG. 2b can be produced; it is an alternative to the variant according to FIG. 8. Steps 900 to 970 correspond to steps 800 to 870 according to FIG. 8 or thus also to steps 500 to 570 according to FIG. 5, but with the following differences. Therefore, the same elements or components as in FIG. 5 are designated by the same reference signs.

In step 900, in addition to step 500 and as in step 800, a p− or p+ implantation is realized, specifically in the zone of the future channel region 108b and the first partial shielding region 116 (these two zones are not yet differentiated from one another at this point in time). The source layer 109 is implanted thereafter, for example.

In step 910, as in step 510, the gate trench 105 is formed, e.g. etched against the mask 512, so that the pattern as shown for step 910 is created.

In step 920, a masked n-implantation 926 is realized by means of oblique implantations and/or oblique rotating implantation into the gate trench 105 using the mask 512, as a result of which the p-doping already present in the channel layer is partially compensated for and the net doping concentration is reduced. Thus, the channel region 108b and the laterally adjacent first partial shielding region 116 are generated.

In addition to the cross-section according to FIG. 2b, an implantation is also carried out in the bottom of the gate trench 105, unless this is prevented by further measures in the process (e.g., patternable materials acting as masking).

Steps 930 to 970 then correspond to steps 830 to 870.

In a further embodiment, for example, the first partial shielding region 116 is omitted and only the second partial shielding region 110, which is self-aligned to the gate trench 105, is used. Corresponding process steps for generating the first partial shielding region 116 can be omitted. Here, the body zone can be designed as a retrograde profile.

In a further embodiment, the first partial shielding region 116 is omitted and only the second shielding trench 118 self-aligned to the gate trench 105 and the self-aligned second partial shielding region 110 are used. Corresponding process steps for generating the first partial shielding region 116 can be omitted.

Due to the use of self-alignment in the described manufacturing methods, the variation between different components is small. This leads to increased yield and/or lower guaranteed tolerances in manufacturing

The present invention can not only be applied to components with homogeneous epi-doping, but can also be used for variable, e.g. stepped or gradually changing epi-doping, as well as for superjunction concepts.

The implantation profile of 116 may not be locally constant, e.g. retrograde; the implantation profile of 110 may not be locally constant, e.g. retrograde.

Furthermore, the described self-alignment for a shielding region can be applied not only to the illustrated cross-section of a field-effect transistor (or MOS/MIS control head), but can also be used for other cross-sections, in particular in a case where a p-doped additional shielding zone is provided below the gate trench, wherein this additional shielding zone can be connected to the source potential and can touch the gate trench 105.

1-10. (canceled)

11. A method for producing a semiconductor component, comprising the following steps:
providing a substrate and/or drain layer, a first-type doped drift and/or a first-type doped spread layer applied to the substrate and/or drain layer, a channel layer applied to the drift and/or spread layer, and a first-type doped source layer inserted into the channel layer and/or applied to the channel layer;
forming a gate trench, which extends in a vertical direction from the source layer into the drift and/or spread layer; and
forming, via implantation, using self-alignment, a second-type doped shielding region, which extends in the vertical direction into the drift and/or spread layer, wherein the shielding region is formed in such a way that the shielding region has a predefined lateral distance from the gate trench, so that a channel region corresponding to the predefined lateral distance remains in the channel layer, and wherein the shielding region is formed in such a way that at least a part of the shielding region extends in the vertical direction to below the gate trench.

12. The method according to claim 11, wherein the semiconductor component is a transistor.

13. The method according to claim 11, wherein forming the shielding region includes:
forming, via implantation, and using a first mask for self-alignment, a first partial shielding region of the shielding region, wherein a lateral width of the first mask is selected in accordance with the predefined lateral distance of the shielding region from the gate trench; and
forming, via implantation, and using a second mask for self-alignment, a second partial shielding region of the shielding region, wherein the second partial shielding region extends in the vertical direction to below the gate trench and deeper than the first partial shielding region, and wherein the second partial shielding region is arranged in the lateral direction at most as close to the gate trench as the first partial shielding region.

14. The method according to claim 11, further comprising, prior to forming the shielding region:
forming a first shielding trench, which extends in the vertical direction into the channel layer and is spaced further from the gate trench in the lateral direction than the shielding region.

15. The method according to claim 13, further comprising, after forming the first partial shielding region and prior to forming the second partial shielding region:
forming a second shielding trench, which extends in the vertical direction into the channel layer and is spaced further from the gate in the lateral direction than the first shielding trench.

16. The method according to claim 11, wherein forming the shielding region includes:
forming, via implantation, a first partial shielding region of the shielding region and the channel region, in such a way that the channel layer is doped in accordance with the first partial shielding region and that the channel region is formed by means of counter-doping,
forming, via implantation, and using a mask for self-alignment, a second partial shielding region of the shielding region, wherein the second partial shielding region extends in the vertical direction to below the gate trench and deeper than the first partial shielding region, and wherein the second partial shielding region is arranged in the lateral direction at most as close to the gate trench as the first partial shielding region.

17. The method according to claim 16, wherein the formation of the first partial shielding region and the channel region is carried out prior to the formation of the gate trench, and wherein forming the gate trench includes removing a part of the channel layer in such a way that the channel region remains.

18. The method according to claim 16, wherein the formation of the first partial shielding region is carried out prior to the formation of the gate trench, wherein the formation of the channel region is carried out after the formation of the gate trench and, via oblique implantation, over the gate trench.

19. The method according to claim 11, further comprising:
inserting a gate with a gate electrode into the gate trench, in such a way that the gate borders on the source layer and the channel layer.

20. A semiconductor component, comprising:
a substrate and/or drain layer;
a first-type doped drift and/or a first-type doped spread layer applied to the substrate and/or drain layer;
a channel layer applied to the drift and/or spread layer;
a first-type doped source layer inserted into the channel layer and/or applied to the channel layer;
a gate trench, which extends in a vertical direction from the source layer into the drift and/or spread layer; and
a second-type doped shielding region, which extends in the vertical direction into the drift and/or spread layer, wherein the shielding region is self-aligned with a predefined lateral distance from the gate trench, so that a channel region corresponding to the predefined lateral distance is formed in the channel layer, and wherein at least a part of the shielding region extends in the vertical direction to below the gate trench.

21. The semiconducter component according to claim 20, wherein the semiconductor component is a transistor.

22. The semiconductor component according to claim 20, wherein the semiconductor component is produced by:
providing the substrate and/or drain layer, the first-type doped drift and/or the first-type doped spread layer applied to the substrate and/or the drain layer, the channel layer applied to the drift and/or spread layer, and the first-type doped source layer inserted into the channel layer and/or applied to the channel layer;
forming the gate trench, which extends in thea vertical direction from the source layer into the drift and/or spread layer; and
forming, via implantation, using self-alignment, the second-type doped shielding region, which extends in the vertical direction into the drift and/or spread layer, wherein the shielding region is formed in such a way that the shielding region has a predefined lateral distance from the gate trench, so that the channel region corresponding to the predefined lateral distance remains in the channel layer, and wherein the shielding region is formed in such a way that the at least a part of the shielding region extends in the vertical direction to below the gate trench.
